(19) United States
(12) Patent Application Publication
(10) Pub. No.: US 2013/0026558 A1
(43) Pub. Date: Jan. 31, 2013

(54) SEMICONDUCTOR DEVICES INCLUDING VARIABLE RESISTANCE MATERIAL AND METHODS OF FABRICATING THE SAME

(71) Applicants: Sang-hun Jeon, Seoul (KR); In-kyeong Yoo, Yongin-si (KR); Chang-jung Kim, Yongin-si (KR); Young-bae Kim, Seoul (KR)

(72) Inventors: Sang-hun Jeon, Seoul (KR); In-kyeong Yoo, Yongin-si (KR); Chang-jung Kim, Yongin-si (KR); Young-bae Kim, Seoul (KR)

(73) Assignee: SAMSUNG ELECTRONICS CO., LTD., Suwon-si (KR)

(21) Appl. No.: 13/451,688

(22) Filed: Apr. 20, 2012

(30) Foreign Application Priority Data
Jul. 29, 2011 (KR) 10-2011-0076166

(51) Int. Cl. H01L 29/792; H01L 21/336

(52) U.S. Cl. 257/324; 438/156; 438/270; 257/E29.309; 257/E21.423

(57) ABSTRACT

The semiconductor device includes an insulating substrate, a channel layer over the insulating substrate, a gate at least partially extending from an upper surface of the channel layer into the channel layer, a source and a drain respectively at opposing sides of the gate on the channel layer, a gate insulating layer surrounding, the gate and electrically insulating the gate from the channel layer, the source, and the drain, and a variable resistance material layer between the insulating substrate and the gate.

### CROSS-REFERENCE TO RELATED APPLICATIONS

This application claims the benefit of priority under 35 U.S.C. §119(e) from Korean Patent Application No. 10-2011-0076166, filed on Jul. 29, 2011, in the Korean Intellectual Property Office, the disclosure of which is incorporated herein by reference in its entirety.

### BACKGROUND

1. Field

Example embodiments relate to semiconductor devices including a variable resistance material and/or methods of manufacturing the semiconductor devices, and more particularly, to semiconductor devices including a variable resistance material, methods of manufacturing the semiconductor devices, and/or non-volatile memory devices including the semiconductor devices.

2. Description of the Related Art

A material having variable resistance in an electric field and/or a magnetic field, or according to application of an electric current/voltage, is being applied in various ways in non-volatile memory devices or logic circuits. For example, in a magnetic tunnel junction (MTJ) device, a variable resistance material that is in a high-resistance state and a low-resistance state according to a magnetization direction is used. In addition, a resistive random access memory (RRAM) generally uses a transition metal oxide, which has a resistance that varies according to applied voltage.

Memory devices, or logic circuits, require a switching device for applying various kinds of voltage (e.g., a set voltage, a reset voltage, or a read voltage) to the variable resistance material. The memory devices, or logic circuits, generally have a structure in which, for example, one switching device and one variable resistance material are connected in series with each other. A transistor is generally used as the switching device. However, a diode may also be used as the switching device. For example, a structure, in which one transistor and one variable resistance material are connected to each other, may be referred to as 1TR-1R structure.

Recently, a technology for combining a switching device and a variable resistance material as one device has been attempted. In this case, the one device may simultaneously perform a switching function and a memory function.

### SUMMARY

Example embodiments relate to semiconductor devices including a variable resistance material and/or methods of manufacturing the semiconductor devices, and more particularly, to semiconductor devices including a variable resistance material, methods of manufacturing the semiconductor devices, and/or non-volatile memory devices including the semiconductor devices.

Provided is a semiconductor device including a variable resistance material which resistance varies according to an applied voltage, and the semiconductor device is capable of simultaneously performing a switching function and a non-volatile memory function.

Provided is also a method of manufacturing the semiconductor device.

Additional aspects will be set forth in part in the description which follows and, in part, will be apparent from the description, or may be learned by practice of the presented embodiments.

According to an example embodiment, a semiconductor device includes an insulating substrate; a channel layer over the insulating substrate; a gate at least partially extending from an upper surface of the channel layer to an inner portion of the channel layer; a source and a drain respectively at both (or, alternatively, opposing) sides of the gate on the channel layer; a gate insulating layer surrounding the gate and electrically insulating the gate from the channel layer, the source, and the drain; and a variable resistance material layer between the insulating substrate and the gate.

The variable resistance material layer directly contacts the gate.

The gate insulating layer is between the variable resistance material layer and the gate.

The variable resistance material layer has a round bottom surface, a central portion of the round bottom surface of the variable resistance material layer that contacts the insulating substrate, and a peripheral portion of the round bottom surface that contacts the channel layer.

The channel layer is formed of a single crystalline semiconductor doped with a first conductive dopant. The source and the drain are formed of a single crystalline semiconductor doped with a second conductive dopant electrically opposite to the first conductive dopant.

The variable resistance material layer may include a first variable resistance material layer with oxygen vacancy defects and a second variable resistance material layer with less oxygen vacancy defects than the first variable resistance material layer.

The first variable resistance material layer and the second variable resistance material layer are sequentially disposed in a direction (or, alternatively, in a path) in which current flows.

The first variable resistance material layer and the second variable resistance material layer are adjacent to each other on (or, alternatively, over) the insulating substrate, and contact both the insulating substrate and the gate.

According to another example embodiment, a semiconductor device includes a channel layer; a source and a drain respectively on an upper portion of the channel layer; a variable resistance material layer in a central upper portion of the channel layer between the source and the drain; a gate over the variable resistance material layer; and a gate insulating layer surrounding the gate.

The gate insulating layer surrounds at least a lower surface of the gate.

The gate insulating layer is between the lower surface of the gate and the channel layer and between the lower surface of the gate and the variable resistance material layer.

The variable resistance material layer directly contacts the gate, and the gate insulating layer is between the lower surface of the gate and the channel layer.

The semiconductor device may further include an insulating layer on both side surfaces of the channel layer to electrically insulate the semiconductor device from another semiconductor device of an adjacent cell.

The semiconductor device may further include a passivation layer covering the source and the drain and one of surrounding the gate and the gate insulating layer.

The semiconductor device may further include a source electrode and a drain electrode extending through the passivation layer, and electrically connected to the source and the drain, respectively.

The variable resistance material layer at least partially extends into the channel layer, and the variable resistance material layer protrudes from the channel layer.

The channel layer is doped with a first conductive dopant, and the source and the drain are doped with a second conductive dopant which is electrically opposite to the first conductive dopant.

The semiconductor device may further include a doped region in a portion of the channel layer surrounding a lower portion of the variable resistance material layer. The doped region is doped with the first conductive dopant at a higher doping concentration that a remaining portion of the channel layer.

The variable resistance material layer may include a first variable resistance material layer with oxygen vacancy defects and a second variable resistance material layer with less oxygen vacancy defects than the first variable resistance material layer.

The first variable resistance material layer and the second variable resistance material layer are sequentially disposed in a direction (or, alternatively, path) in which current flows between the source and the drain.

The variable resistance material layer may include the first variable resistance material layer, the second variable resistance material layer, and a third variable resistance material layer that are sequentially disposed in a direction (or alternatively, path) in which current flows between the source and the drain. The third variable resistance material layer and the first variable resistance material layer may be identical.

According to a yet still further example embodiment, a semiconductor device includes a multi-layered channel including a first channel layer and a second channel layer, the second channel layer including a variable resistance material; a source and a drain respectively on opposing ends of the multi-layered channel; and a gate electrically insulated from the first channel layer, the source and the drain. The second channel layer is interposed in an electrical path between the gate and the first channel layer.

One of the second channel layer and the gate may be recessed within the first channel layer, and protrudes from an upper surface of the first channel layer.

According to another example embodiment, a method of manufacturing a semiconductor device includes preparing a structure including an insulating substrate, a channel layer formed on the insulating substrate, and a source and a drain respectively disposed on an upper portion of the channel layer; forming a recess region in the channel layer by partially etching the channel layer between the source and the drain; forming a first gate insulating layer on an entire inner wall of the recess region; partially removing both the first gate insulating layer formed on a bottom surface of the recess region and the channel layer to expose a surface of the insulating substrate; forming a variable resistance material layer on the surface of the insulating substrate in the recess region; and forming a gate by depositing (or, alternatively, forming) a gate electrode material in the recess region.

The preparing of a structure may include preparing a transistor including the insulating substrate, the channel layer formed on the insulating substrate, the source and the drain respectively disposed on an upper surface of the channel layer, a temporary gate partially formed between the source and the drain on the upper surface of the channel layer, an insulating layer surrounding a lower surface of the temporary gate, and a passivation layer formed on the upper surface of the channel layer, and surrounding the gate insulating layer and the temporary gate; polishing the passivation layer to expose the temporary gate; and forming a through hole in the passivation layer by selectively etching the temporary gate and the insulating layer to expose the upper surface of the channel layer.

The forming of a through hole includes removing the gate insulating layer formed under the temporary gate, and a portion of the insulating layer formed on a side surface of the temporary gate remains on a side wall of the through hole of the passivation layer.

The forming of a recess region may include partially etching the channel layer exposed through the through hole.

The method may further include forming contact holes in the passivation layer, and forming a source electrode and a drain electrode respectively connected to the source and the drain by depositing (or, alternatively, forming) an electrode material in the contact holes.

The method may further include forming a second gate insulating layer on the variable resistance material layer, after the forming of a variable resistance material layer on the surface of the insulating substrate in the recess region.

The channel layer is etched such that the recess region has a round bottom surface.

The forming of a variable resistance material layer on the surface of the insulating substrate in the recess region may include forming a first variable resistance material layer on an inner wall of the recess region and removing the first variable resistance material layer formed in a central portion of the recess region; forming oxygen vacancy defects in the first variable resistance material layer by using an ion injection method; and forming a second variable resistance material layer in the central portion of the recess region.

According to another example embodiment, method of manufacturing a semiconductor device includes preparing a structure including a channel layer, a source and a drain formed by doping an upper surface of the channel layer, a temporary gate disposed between the source and the drain on the upper surface of the channel layer, a gate insulating layer surrounding a lower surface and side surfaces of the temporary gate, and a passivation layer formed on the channel layer to surround the gate insulating layer; forming an opening by removing the temporary gate to expose a bottom surface of the gate insulating layer; forming a recess region in the channel layer by partially etching both the bottom surface of the gate insulating layer in the opening and the channel layer below the gate insulating layer; forming a variable resistance material layer in the recess region; and forming a gate by depositing (or, alternatively, forming) a gate electrode material in the opening on the variable resistance material layer.

The channel layer is formed by doping a single crystalline semiconductor substrate with a first conductive dopant, and the source and the drain are doped with a second conductive dopant which is electrically opposite to the first conductive dopant.

During the forming an opening by removing the temporary gate, the gate insulating layer remains on an inner wall of the opening.

The forming of a recess region may include depositing a mask on the passivation layer and the gate insulating layer; removing portions of the mask to form a mask pattern that surrounds the inner wall of the opening, exposes a central portion of the bottom surface of the opening and covers a peripheral portion of the bottom surface of the opening; and removing the bottom surface of the gate insulating layer that is not covered by the mask pattern and partially removing the channel layer.

The method may further include, after the forming of a variable resistance material layer in the recess region, forming the bottom surface of the gate insulating layer between the mask pattern to cover an upper surface of the variable resistance material layer; and removing the mask pattern formed on side walls of the gate insulating layer.

The method may further include, after the forming of a recess region, forming a doped region in the channel layer around the recess region by injecting ions into the channel layer around the recess region.

The forming of a variable resistance material layer in the recess region may include forming a first variable resistance material layer on an inner wall of the recess region and removing the first variable resistance material layer formed in a central portion of the recess region; forming oxygen vacancy defects in the first variable resistance material layer by using an ion injection method; and forming a second variable resistance material layer in a central portion of the recess region.

According to an even further example embodiment, a method of manufacturing a semiconductor device includes providing a switching structure including a channel layer, a source and a drain on the channel layer, a temporary gate over the channel layer and insulated from the source, the drain and the channel layer by an insulating layer, a passivation layer covering an upper surface of the temporary gate. The method further includes forming an opening that exposes a portion of the channel layer by sequentially polishing the passivation layer from the upper surface of the temporary gate and etching to remove the temporary gate; forming a recess region in the channel layer by removing the insulating layer from a bottom surface of the opening; forming a variable resistance layer in a bottom portion of the recess region and contacting the channel layer; and forming a gate over the variable resistance material layer by filling in a remaining portion of the recess region with a gate electrode material, the gate being insulated from the source, the drain and the channel layer.

Prior to the forming of a variable resistance layer, depositing a gate insulating layer in the recess region; and removing the gate insulating layer from a bottom surface of the recess region and the channel layer under the bottom surface of the recess region to expose an insulating substrate.

### BRIEF DESCRIPTION OF THE DRAWINGS

These and/or other aspects will become apparent and more readily appreciated from the following description of the embodiments, taken in conjunction with the accompanying drawings of which:

FIG. 1 is a schematic cross-sectional view illustrating a semiconductor device, according to an example embodiment;

FIGS. 2A through 2H are schematic cross-sectional views illustrating a method of manufacturing the semiconductor device of FIG. 1;

FIG. 3 is a schematic cross-sectional view illustrating a semiconductor device, according to another example embodiment;

FIG. 4 is a schematic cross-sectional view illustrating a semiconductor device, according to yet another example embodiment;

FIG. 5 is a schematic cross-sectional view illustrating an etching process performed during manufacturing of the semiconductor device of FIG. 4;

FIG. 6 is a schematic cross-sectional view illustrating a semiconductor device, according to still another example embodiment;

FIGS. 7A through 7I are schematic cross-sectional views illustrating a method of manufacturing the semiconductor device of FIG. 6;

FIG. 8 is a schematic cross-sectional view illustrating a semiconductor device, according to still yet another example embodiment;

FIG. 9 is a schematic cross-sectional view illustrating a semiconductor device, according to a further example embodiment;

FIGS. 10A through 10C are schematic cross-sectional views illustrating a method of manufacturing the semiconductor device of FIG. 9; and

FIG. 11 is a schematic cross-sectional view illustrating a semiconductor device, according to a still further example embodiment.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to semiconductor devices including a variable resistance material and/or methods of manufacturing the semiconductor devices, and more particularly, to semiconductor devices including a variable resistance material, methods of manufacturing the semiconductor devices, and/or non-volatile memory devices including the semiconductor devices.

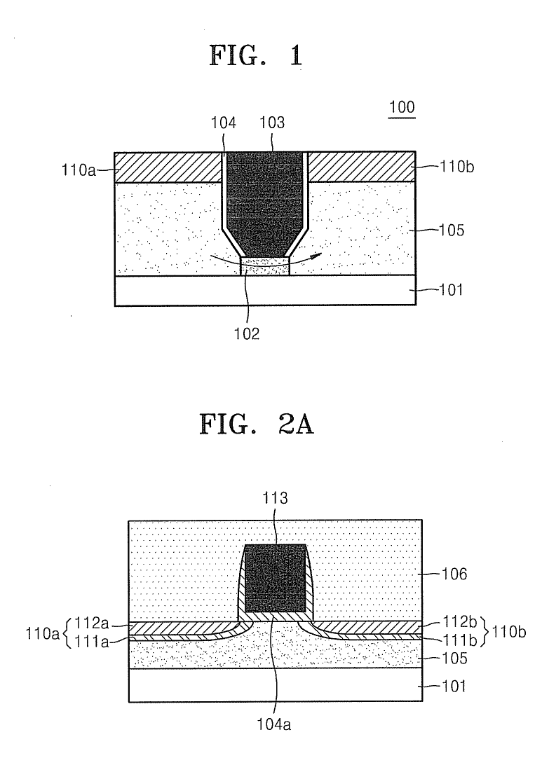

FIG. 1 is a schematic cross-sectional view illustrating a semiconductor device according to an example embodiment.

Referring to FIG. 1, a semiconductor device 100 includes an insulating substrate 101, a channel layer 105 disposed on the insulating substrate 101, a gate 103 at least partially extending from an upper portion of the channel layer 105 to an inner portion of the channel layer 105, a gate insulating layer 104 disposed to surround the gate 103, a source 110a and a drain 110b respectively disposed at both sides of the gate 103, and a variable resistance material layer 102 disposed between the insulating substrate 101 and the gate 103. The gate insulating layer 104 that surrounds the gate 103 and electrically insulates the gate 103 from the channel layer 105, the source 110a, and the drain 110b.

The insulating substrate 101 may be an oxide substrate formed of, for example, SiO₂. In FIG. 1, the insulating substrate 101 is formed to have a single-layer structure. However, example embodiments are not limited thereto, and thus the insulating substrate 101 may be formed to have a multi-layer structure in which a silicon oxide layer is formed on a silicon layer (e.g., a silicon on insulator (SOI) substrate).

The channel layer 105 formed on the insulating substrate 101 may be formed of, for example, a single crystal silicon. Alternatively, the channel layer 105 may be formed of a crystal of any other compound semiconductor having excellent electron mobility. The channel layer 105 may be doped with a p-type dopant, or an n-type dopant. As illustrated in FIG. 1, the channel layer 105 may have a recess channel structure in which a part of the channel layer 105 is recessed.

The gate 103 may extend from the upper surface of the channel layer 105 into at least a part (that is, into a recess region) of the channel layer 105. The gate 103 may be formed of, for example, a polycrystalline silicon (poly-Si) or a metal material. Also, the source 110a and the drain 110b may be disposed at both sides of the gate 103 and on the channel layer 105. When the channel layer 105 is formed of a single crystal silicon doped with a p-type dopant, the source 110a and the drain 110b may be formed of a single crystal silicon doped with an n-type dopant. When the channel layer 105 is doped with an n-type dopant, the source 110a and the drain 110b may be doped with a p-type dopant. Although the source 110a and the drain 110b are formed to have a single-layer structure in FIG. 1, the source 110a and the drain 110b may be formed to have a bi-layered structure including an n doping layer and an n+ doping layer. Meanwhile, the gate insulating layer 104 surrounding the gate 103 electrically insulates the channel layer 105, the source 110a, and the drain 110b from the gate 103. The gate insulating layer 104 may be formed of, for example, SiO₂ or SiNₓ or a high dielectric constant (high-k) material (e.g., HfSiON or ZrSiON).

The variable resistance material layer 102 may be disposed between the insulating substrate 101 and the gate 103. As illustrated in FIG. 1, a lower surface of the variable resistance material layer 102 may directly contact the insulating substrate 101, an upper surface thereof may directly contact the gate 103, and both side surfaces thereof may directly contact the channel layer 105. The variable resistance material layer 102 may be formed of a variable resistance material, which has a resistance that varies according to an applied voltage. For example, when a set voltage is applied to the variable resistance material, the resistance of the variable resistance material is decreased, which is generally referred to as an “ON” state. Also, when a reset voltage is applied to the variable resistance material, the resistance of the variable resistance material is increased, which is generally referred to as an “OFF” state. In general, a resistive random access memory (RRAM) device may store data by using a switching operation between the “ON” state and the “OFF” state of the variable resistance material. Meanwhile, when recorded data is read, a read voltage that does not change the resistance of the variable resistance material may be applied to the variable resistance material.

The variable resistance material used to form the variable resistance material layer 102 may be, for example, a transition metal oxide (TMO). For example, a variable resistance material layer 102 may be formed of at least one selected from Ni oxide, Cu oxide, Ti oxide, Co oxide, Hf oxide, Zr oxide, Zn oxide, W oxide, Nb oxide, TiNi oxide, LiNi oxide, Al oxide, InZn oxide, V oxide, SrZr oxide, SrTi oxide, Cr oxide, Fe oxide, Ta oxide, and compounds thereof. Also, the variable resistance material, which has the variable resistance according to application of the voltage/current, may be used. For instance, a multi-component metal oxide (e.g., Pr₁-xCaxMnO₃ (PCMO) and SrTiO₃ (STO)), or a solid electrolyte material, may be used to form the variable resistance material layer 102.

Operations of the semiconductor device having the above-described structure will now be described.

The semiconductor device 100 has a structure of a transistor including the variable resistance material layer 102 as part of a channel. Thus, if a voltage lower than a threshold voltage is applied to the gate 103, the semiconductor device 100 is in an “OFF” state. Accordingly, even though a voltage is applied to the source 110a and the drain 110b, current is not applied to the channel layer 105 or the variable resistance material layer 102.

If a voltage greater than a threshold voltage is applied to the gate 103, the semiconductor device 100 is in an “ON” state. Then, current may be applied between the source 110a and the drain 110b through the channel layer 105 and the variable resistance material layer 102. As illustrated in FIG. 1, the channel layer 105 is divided into two parts by the variable resistance material layer 102, and thus current applied between the source 110a and the drain 110b should pass through the variable resistance material layer 102. At this time, resistance of the variable resistance material layer 102 may vary according to a potential difference between the source 110a and the drain 110b.

For example, if the potential difference between the source 110a and the drain 110b is a set voltage, resistance of the variable resistance material layer 102 is decreased. Then, current between the source 110a and the drain 110b increases. Also, if the potential difference between the source 110a and the drain 110b is a reset voltage, the resistance of the variable resistance material layer 102 is increased. Then, current between the source 110a and the drain 110b decreases. If the potential difference between the source 110a and the drain 110b is a read voltage, the resistance of the variable resistance material layer 102 does not change. In this regard, a resistance state of the variable resistance material layer 102 may be read by measuring current between the source 110a and the drain 110b. Accordingly, an ON/OFF switching operation of the semiconductor device 100 may be performed according to a voltage applied to the gate 103. Also, the resistance of the variable resistance material layer 102 may be changed according to a voltage applied to the source 110a and the drain 110b, and an operation for reading a resistance value of the variable resistance material layer 102 may be performed according to a voltage applied to the source 110a and the drain 110b.

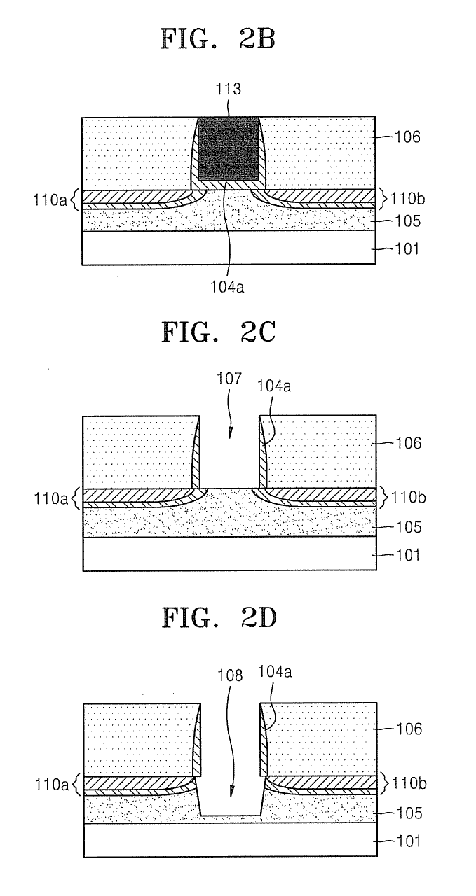

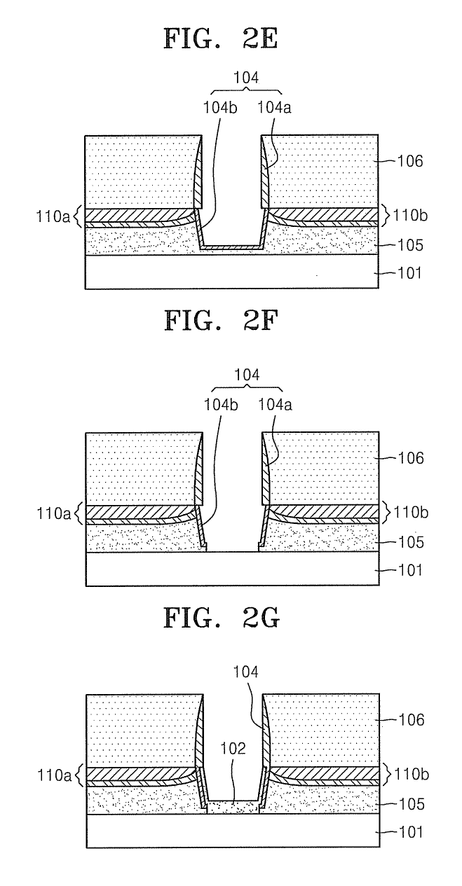

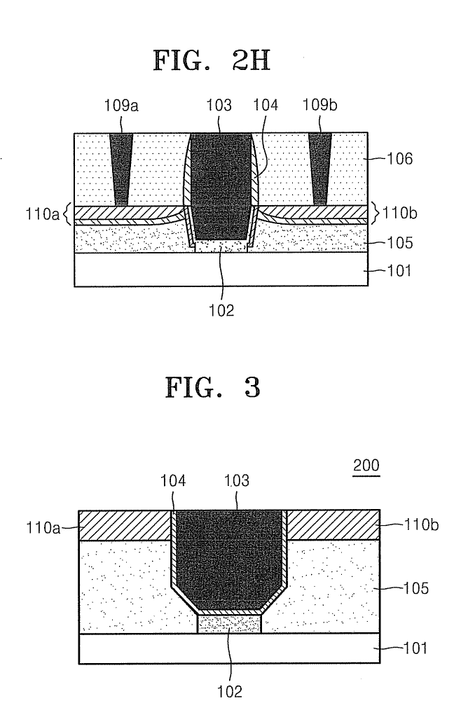

FIGS. 2A through 2H are schematic cross-sectional views illustrating a method of manufacturing the semiconductor device of FIG. 1.

First, as illustrated in FIG. 2A, a top-gate transistor is formed on an insulating substrate 101 by using a method of manufacturing a general transistor. That is, referring to FIG. 2A, the top gate-type transistor may include the insulating substrate 101, a p-type channel layer 105, a gate insulating layer 104a and a gate 113 that are partially formed on the p-type channel layer 105, an n-type source 110a and an n-type drain 110b that are respectively, formed at side portions of the gate 113 in an upper area of the p-type channel layer 105, and a passivation layer 106 formed on the channel layer 105 so as to surround the gate insulating layer 104a and the gate 113. Alternatively, the p-type channel layer 105, the n-type source 110a, and the n-type drain 110b may be an n-type channel layer, a p-type source, and a p-type drain. The source 110a may include an n doped region 111a and an n+ doped region 112a that is formed by doping an upper portion of the n doped region 111a with higher concentration of the dopant. Similarly to, the drain 110b may include an n doped region 111b and an n+ doped region 112b. In this regard, the gate 113 may be a temporary gate, rather than the gate 103 of the semiconductor device 100 to be finally formed.

Referring to FIG. 2B, the passivation layer 106 is removed to expose the gate 113 by using a general chemical mechanical polishing (CMP) method.

Referring to FIG. 2C, the gate 113 and the gate insulating layer 104a may be selectively removed to expose an upper surface of the channel layer 105 by using a dry etching method. When the gate 113 and the gate insulating layer 104a are removed, a through hole 107 may be simultaneously formed in the passivation layer 106. In this regard, the gate insulating layer 104a formed under the gate 113 is partially removed so that portions of the gate insulating layer 104a formed at side surfaces of the gate 113 remain on side walls of the through hole 107 in the passivation layer 106.

Referring to FIG. 2D, a recess region 108 may be formed in the channel layer 105 by partially etching the channel layer 105 exposed through the through hole 107. In this regard, a bottom surface of the recess region 108 may be formed in the channel layer 105. In the above-described process, the source 110a and the drain 110b formed under the gate insulating layer 104a may be partially removed.

Referring to FIG. 2E, a gate insulating layer 104b is formed on the entire inner wall of the recess region 108, that is, on the exposed surfaces of the channel layer 105, the source 110a, and the drain 110b. The exposed surfaces of the channel layer 105, the source 110a, and the drain 110b may be completely covered by the gate insulating layer 104b. In this regard, the gate insulating layer 104b formed on the channel layer 105, the source 110a, and the drain 110b may be connected to the gate insulating layers 104a formed on the side walls of the through hole 107, thereby forming the gate insulating layer 104.

Next, as illustrated in FIG. 2F, a part of the gate insulating layer 104b, which is formed on the bottom surface of the recess region 108, and a part of the channel layer 105, which is formed under the bottom surface of the recess region 108, are sequentially removed so as to expose a surface of the insulating substrate 101 by using an anisotropic etching method.

Referring to FIG. 2G, a variable resistance material layer 102 is formed on the exposed surface of the insulating substrate 101 in the recess region 108 through, for example, chemical vapor deposition (CVD) or physical vapor deposition (PVD). The variable resistance material layer 102 covers the entire lower portion of the gate insulating layer 104b, but example embodiments are not limited thereto. That is, the variable resistance material layer 102 may partially fill in the recess region 108, and a part of the lower portion of the gate insulating layer 104b may be exposed.

Referring to FIG. 2H, the gate 103 may be formed by depositing (or, alternatively, forming) a gate electrode material in the through hole 107 and the recess region 108. Then, contact holes may be formed in the passivation layers 106 respectively formed at both sides of the gate 103 by using an etching method, and an electrode material may be filled in each contact hole to form a source electrode 109a and a drain electrode 109b respectively connected to the source 110a and the drain 110b. Alternatively, before the gate 103 is formed in the through hole 107 and the recess region 108, the contact hole may be formed by etching the passivation layers 106 formed at both sides of the through hole 107. Then, the gate 103, the source electrode 109a, and the drain electrode 109b may be simultaneously formed by depositing (or, alternatively, forming) an electrode material in the through hole 107, the recess region 108, and the contact holes.

In general, the variable resistance material layer 102 loses a resistance variation characteristic at a high temperature. Thus, during manufacturing of a semiconductor device, a high temperature process may be performed after forming the variable resistance material layer 102. When a high temperature process is performed, the variable resistance material layer 102 deteriorates, thereby decreasing an operational reliability of the semiconductor device. However, when the semiconductor device 100 is manufactured by using the method described with reference to FIGS. 2A through 2H, high temperature processing is not performed after the variable resistance material layer 102 is formed, and thus a risk of deteriorating or deforming the variable resistance material layer 102 due to the high temperature is low.

Meanwhile, in the example embodiments illustrated in FIGS. 1, 2G, and 2H, the variable resistance material layer 102 that directly contacts the gate 103 is formed thereon. However, the gate insulating layer 104 may further be disposed between the variable resistance material layer 102 and the gate 103.

FIG. 3 is a schematic cross-sectional view illustrating a semiconductor device according to another example embodiment.

The embodiment illustrated in FIG. 3 is different from that illustrated in FIG. 1 because the gate insulating layer 104 in FIG. 3 is further disposed between the variable resistance material layer 102 and the gate 103.

A method of manufacturing the semiconductor device of FIG. 3 will now be described.

First, processes illustrated in FIGS. 2A through 2G are sequentially performed. The variable resistance material layer 102 is formed as illustrated in FIG. 2G, and then the gate insulating layer 104 is formed on the variable resistance material layer 102. Then, the gate 103 is formed by using the method described with reference to FIG. 2H, thereby completing the semiconductor device 200 illustrated in FIG. 3.

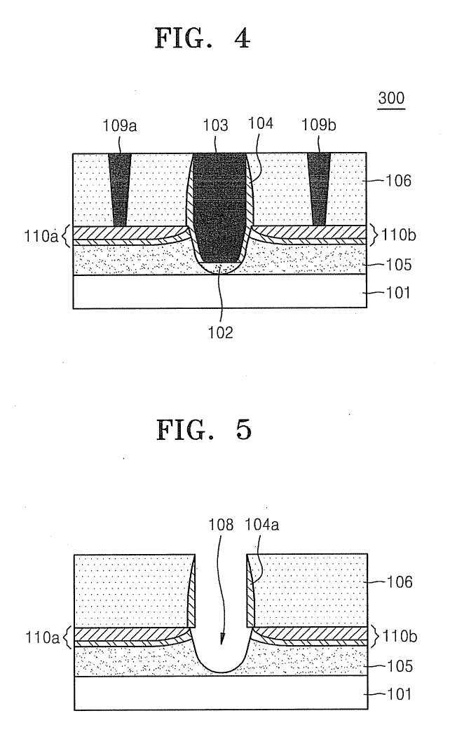

FIG. 4 is a schematic cross-sectional view illustrating a semiconductor device according to yet another example embodiment.

In the semiconductor devices illustrated in FIGS. 1 and 3, the recess region 108 formed in the channel layer 105 has a flat bottom surface, and the variable resistance material layer 102 also has a flat bottom surface. Referring to FIG. 4, in the semiconductor device 300, if the recess region 108 formed in the channel layer 105 has a round bottom surface, the variable resistance material layer 102 may also have a round bottom surface. Thus, a central portion of the round bottom surface of the variable resistance material layer 102 may contact the insulating substrate 101 and a peripheral portion of the round bottom surface thereof may contact the channel layer 105. In this case, changes in a threshold voltage of the semiconductor device 300 due to a process error may be reduced, and the threshold voltage of the semiconductor device 300 may be safely maintained.

Now, a method of manufacturing the semiconductor device shown in FIG. 4 will be described.

The manufacturing process of the semiconductor device 300 illustrated in FIG. 4 may include the processes illustrated in FIGS. 2A through 2C.

FIG. 5 is a schematic cross-sectional view illustrating an etching process performed during manufacturing of the semiconductor device of FIG. 4.

Referring to FIG. 5, after performing the process illustrated in FIG. 2C, the channel layer 105 may be etched in such a way that the recess region 108 formed in the channel layer 105 has a round bottom surface by using, for example, an anisotropic etching method. Then, if the processes illustrated in FIGS. 2E through 2H are performed, the semiconductor device 300 having the round recess channel illustrated in FIG. 4 may be obtained.

The above-described semiconductor devices 100, 200, and 300 have the channel layer 105 formed on the insulating substrate 101 (e.g., an SOI substrate), and the channel layer 105 having a recess structure. However, a semiconductor device having the same function as the above-described semiconductor devices 100, 200, and 300 may be formed on a semiconductor bulk substrate (e.g., silicon).

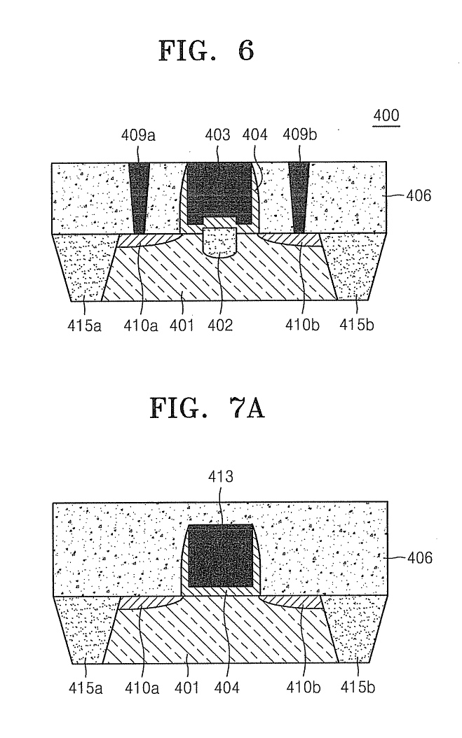

FIG. 6 is a schematic cross-sectional view illustrating a semiconductor device according to still another example embodiment.

Referring to FIG. 6, the semiconductor device 400 according to the present example embodiment may include a channel layer 401, a source 410a and a drain 410b respectively disposed at both (or, alternatively, opposing) upper portions of the channel layer 401, a variable resistance material layer 402 disposed in a central upper portion of the channel layer 401 between the source 410a and the drain 410b, a gate 403 disposed over the variable resistance material layer 402, and a gate insulating layer 404 surrounding the gate 403. As illustrated in FIG. 6, the gate insulating layer 404 may surround at least a lower surface of the gate 403 and may selectively surround side surfaces of the gate 403. In FIG. 6, the gate insulating layer 404 is disposed between the gate 403 and the variable resistance material layer 402, or alternatively, the variable resistance material layer 402 may directly contact the gate 403. In this case, the gate insulating layer 404 may not be disposed between the lower surface of the gate 403 and the variable resistance material layer 402, and may be disposed only between the lower surface of the gate 403 and the channel layer 401.

As illustrated in FIG. 6, insulating layers 415a and 415b may further be disposed on both (or, alternatively, opposing) side surfaces of the channel layer 401 so as to be electrically insulated from another semiconductor device of an adjacent cell. The insulating layers 415a and 415b maybe, for example, a shallow trench isolation (STI) feature. Also, a passivation layer 406 may further be formed to cover the insulating layers 415a and 415b, a source 410a, and a drain 410b. The passivation layer 406 may be formed to surround the gate 403 or the gate insulating layer 404. Also, a source electrode 409a and a drain electrode 409b may further be formed to pass (or extend) through the passivation layer 406 to be electrically connected to the source 410a and the drain 410b, respectively. In FIG. 6, the source 410a and the drain 410b are formed to have a single-layer structure. However, example embodiments are not limited thereto, and the source 410a and the drain 410b may be formed to have a bi-layered structure including two layers having different doping concentrations as described above.

At least a part of the variable resistance material layer 402 extends into the channel layer 401, as illustrated in FIG. 6. Also, in FIG. 6, the variable resistance material layer 402 protrudes upward from the channel layer 401, but example embodiments are not limited thereto. For example, an upper surface of the variable resistance material layer 402 and an upper surface of the channel layer 401 may be on the same level, or alternatively, the upper surface of the variable resistance material layer 402 may be slightly lower than that of the channel layer 401.

In the example embodiment described with reference to FIG. 6, the channel layer 401 may be formed by doping, for example, a single crystalline silicon bulk substrate with a p-type dopant. In this case, the source 410a and the drain 410b are doped with an n-type dopant. Alternatively, the channel layer 401 may be formed by doping a single crystalline silicon bulk substrate with an n-type dopant. In this case, the source 410a and the drain 410b are doped with a p-type dopant. Alternatively, the channel layer 401 may be formed of a single crystal silicon of any other compound semiconductor instead of silicon.

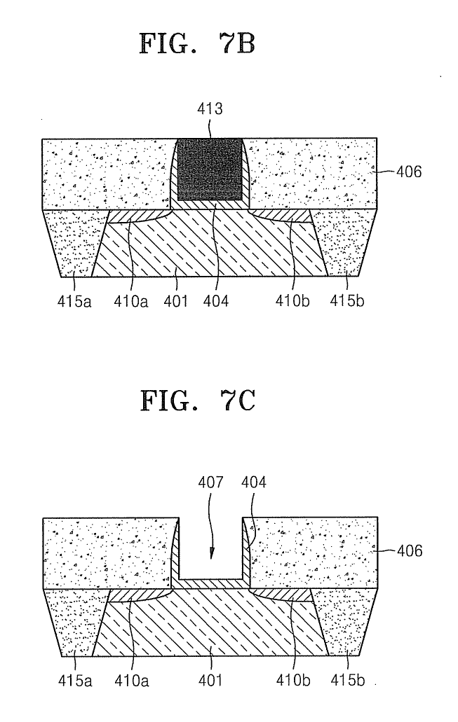

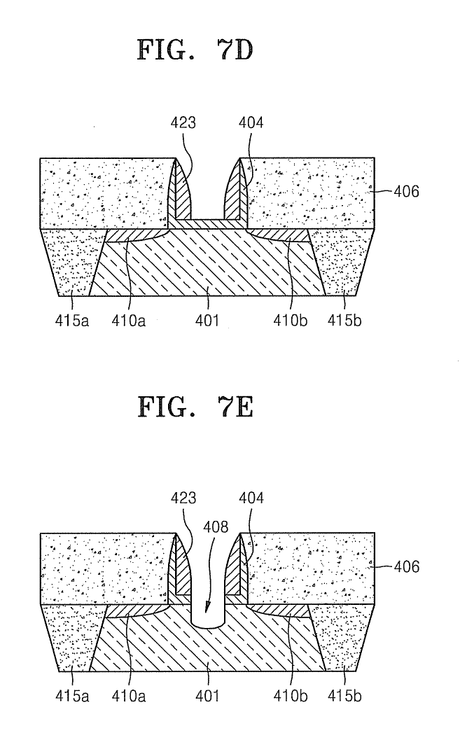

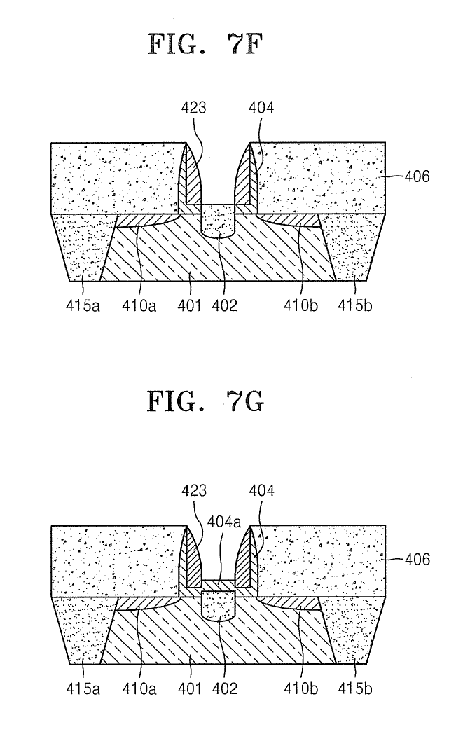

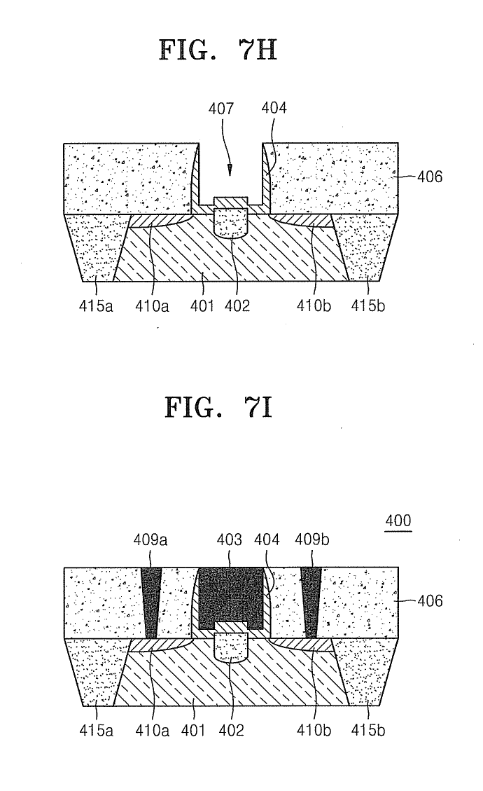

FIGS. 7A through 7I are schematic cross-sectional views illustrating a method of manufacturing the semiconductor device of FIG. 6.

First, as illustrated in FIG. 7A, a top-gate transistor is formed on a single crystalline silicon bulk substrate by using a method of manufacturing a general transistor. That is, referring to FIG. 7A, the top gate-type transistor may include the channel layer 401 formed by doping a single crystalline silicon bulk substrate, the source 410a and the drain 410b formed by doping both upper surfaces of the channel layer 401, the gate insulating layer 404 and the gate 413 that are disposed between the source 410a and the drain 410b, insulating layers 415a and 415b formed on both side surfaces of the channel layer 401, and the passivation layer 406 covering the gate insulating layer 404, the gate 413, the insulating layers 415a and 415b, the source 410a, and the drain 410b. For example, when the channel layer 401 is doped with a p-type dopant, the source 410a and the drain 410b may be doped with an n-type dopant. Also, when the channel layer 401 is doped with an n-type dopant, the source 410a and the drain 410b may be doped with a p-type dopant. The gate 413 may be formed of, for example, polycrystalline silicon. In this regard, the gate 413 formed of polycrystalline silicon may be a temporary gate, not the gate 403 of the semiconductor device 400 to be finally formed.

Referring to FIG. 7B, the passivation layer 406 is removed to expose the gate 413 by using a CMP method.

Referring to FIG. 7C, the gate 413 formed of polycrystalline silicon is completely removed by using an etching method. Then, only the gate insulating layer 404 surrounding the gate 413 remains, and an opening 407 is formed in the gate insulating layer 404. Thus, only the gate insulating layer 404 remains on an inner wall of the opening 407.

Next, referring to FIG. 7D, the inner wall of the opening 407 formed in the gate insulating layer 404 is surrounded by a mask pattern 423 formed of, for example, polycrystalline silicon. Only a central portion of a bottom surface of the opening 407 is exposed, and a peripheral portion of the bottom surface thereof is covered by the mask pattern 423. A process of forming the mask pattern 423 of FIG. 7D may include uniformly and entirely depositing a polycrystalline silicon mask (not shown) on the passivation layer 406 and the gate insulating layer 404. Then, portions of the polycrystalline silicon mask on the upper surfaces of the passivation layer 406 and the gate insulating layer 404 are removed using an etching method such that the polycrystalline silicon mask only remains on the inner wall of the opening 407 formed in the gate insulating layer 404, thereby forming the mask pattern 423.

Then, referring to FIG. 7E, a bottom surface of the gate insulating layer 404 not covered (or, alternatively, exposed) by the mask pattern 423 is removed, and then a part of the channel layer 401 disposed under the gate insulating layer 404 is removed through etching. Thus, referring to FIG. 7E, the recess region 408 may be partially formed in the channel layer 401, and at this time, a bottom surface of the recess region 408 is formed inside the channel layer 401.

Then, referring to FIG. 7F, the variable resistance material layer 402 is filled in the recess region 408 by using, for example, a CVD method or a PVD method. In FIG. 7F, the variable resistance material layer 402 is formed to reach (or, alternatively, to contact) the gate insulating layer 404 formed on the channel layer 401, but example embodiments are not limited thereto. For example, an upper surface of the variable resistance material layer 402 and an upper surface of the channel layer 401 may be on the same level, or alternatively, the upper surface of the variable resistance material layer 402 may be slightly lower than that of the channel layer 401.

Referring to FIG. 7G, after the variable resistance material layer 402 is formed, a bottom surface 404a of the gate insulating layer 404 is formed between the mask pattern 423 to cover the upper surface of the variable resistance material layer 402. Then, the gate insulating layer 404 formed on side walls of the opening 407 is connected to the bottom surface 404a.

Referring to FIG. 7H, the mask pattern 423 formed on the side walls of the gate insulating layer 404 are removed, and thus only the gate insulating layer 404 remains in the opening 407.

Finally, referring to FIG. 7I, the gate 403 may be formed by depositing (or, alternatively, forming) a gate electrode material in the opening 407. Then, contact holes may be formed in the passivation layers 406 respectively formed at both sides of the gate 403 by using an etching method, and then an electrode material may be filled in each contact hole to form a source electrode 409a and a drain electrode 409b respectively connected to the source 410a and the drain 410b. Alternatively, before the gate 403 is formed in the opening 407, the contact hole may be formed by etching the passivation layers 406 formed at both sides of the opening 407. Then, the gate 403, the source electrode 409a, and the drain electrode 409b may be simultaneously formed by depositing (or, alternatively, forming) an electrode material in the opening 407 and the contact holes.

The semiconductor device 400 illustrated in FIG. 6 may be manufactured by using the above-described method. In FIG. 6, the gate insulating layer 404 is formed between the variable resistance material layer 402 and the gate 403. However, similar to the semiconductor device 100 illustrated in FIG. 1, the gate 403 may directly contact the variable resistance material layer 402. In this case, the process of forming the bottom surface 404a of the gate insulating layer 404 illustrated in FIG. 7G may be omitted.

Meanwhile, in the semiconductor devices 100, 200, and 300 illustrated in FIGS. 1, 3, and 4, the channel layer 105 is divided by the variable resistance material layer 102, and thus current applied between the source 110a and the drain 110b should pass through the variable resistance material layer 102. However, in the semiconductor device 400 illustrated in FIG. 6, the channel layer 401 is connected to the source 410a and the drain 410b through the lower portion of the variable resistance material layer 402. Thus, a part of the current, which flows between the source 410a and the drain 410b, may flow to the channel layer 401 without passing through the variable resistance material layer 402. In this case, an amount of the current passing through the variable resistance material layer 402 may not be sufficient.

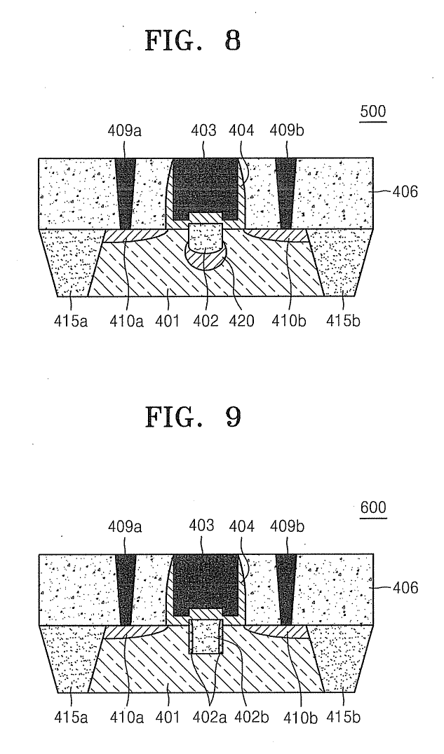

FIG. 8 is a schematic cross-sectional view illustrating a semiconductor device according to still yet another example embodiment.

In the semiconductor device 500 illustrated in FIG. 8, most of current applied between the source 410a and the drain 410b passes through the variable resistance material layer 402.

Referring to FIG. 8, the semiconductor device 500 includes a doped region 420 having a high doping concentration formed by highly doping a part of the channel layer 401 surrounding a lower portion of the variable resistance material layer 402. For example, when the channel layer 401 is doped with a p-type dopant and the source 410a and the drain 410b are doped with an n-type dopant, the doped region 420 may be a p+ doped region. Also, when the channel layer 401 is doped with an n-type dopant and the source 410a and the drain 410b are doped with a p-type dopant, the doped region 420 may be an n+ doped region. In this case, because only a small amount of current detours to the channel layer 401 disposed under the doped region 420, most of the current may be applied to the variable resistance material layer 402. The highly concentrated doped region 420 may be formed by, for example, forming the recess region 408 and then injecting ions to the channel layer 401 around the recess region 408, in the process illustrated in FIG. 7E. Then, the processes illustrated in FIGS. 7F through 7I are performed, thereby completing the semiconductor device 500 illustrated in FIG. 8. Except for the doped region 420 of FIG. 8, the components of the semiconductor device 500 illustrated in FIG. 8 are the same as those of the semiconductor device 400 illustrated in FIG. 6.

A case where the variable resistance material layer 402 is formed to have a single-layer structure has been described above. However, in order to further increase a resistance variation characteristic of the variable resistance material layer 402, the variable resistance material layer 402 may be formed to have a multi-layered structure including at least two layers. For example, when a TiOₓ layer with a relatively large amount of oxygen vacancy defects and a general TiO₂ layer with a relatively small amount of oxygen vacancy defects are stacked in a direction in which current flows between two electrodes, the oxygen vacancy defects move between the TiOₓ layer and the TiO₂ layer, thereby increasing the resistance variation characteristic of the variable resistance material layer 402.

FIG. 9 is a schematic cross-sectional view illustrating a semiconductor device according to a further example embodiment.

Referring to FIG. 9, in the semiconductor 600, the variable resistance material layer 402 may include a first variable resistance material layer 402a and a second variable resistance material layer 402b in a direction in which current flows, that is, in a direction from a source 410a to a drain 410b. For example, the first variable resistance material layer 402a may be formed of TiOₓ having a relatively large amount of oxygen vacancy defects, and the second variable resistance material layer 402b may be formed of TiO₂ having a relatively small amount of oxygen vacancy defects. Alternatively, the first variable resistance material layer 402a may be formed of TiO₂, and the second variable resistance material layer 402b may be formed of TiOₓ.

Although the variable resistance material layer 402 shown in FIG. 9 has a straight bottom surface, example embodiments are not limited thereto. That is, the variable resistance material layer 402 may have a round bottom surface, similar to the semiconductor device shown 400 illustrated in FIG. 6.

The semiconductor device 600 illustrated in FIG. 9 may be formed to have a structure that is the same as that of the semiconductor device 400 illustrated in FIG. 6, except for the variable resistance material layer 402 of FIG. 6.

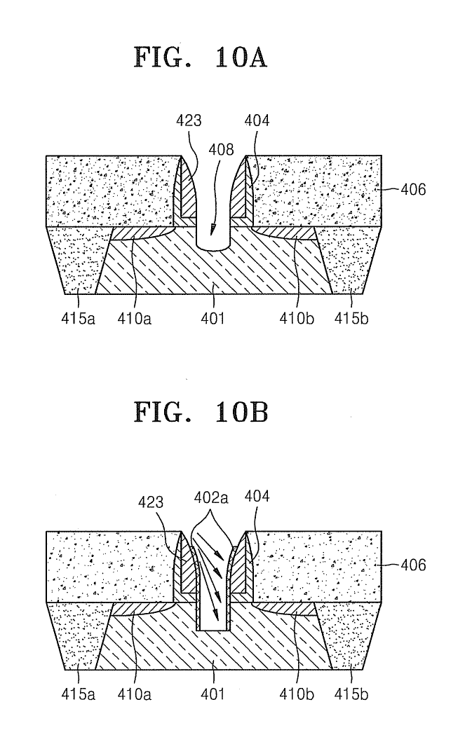

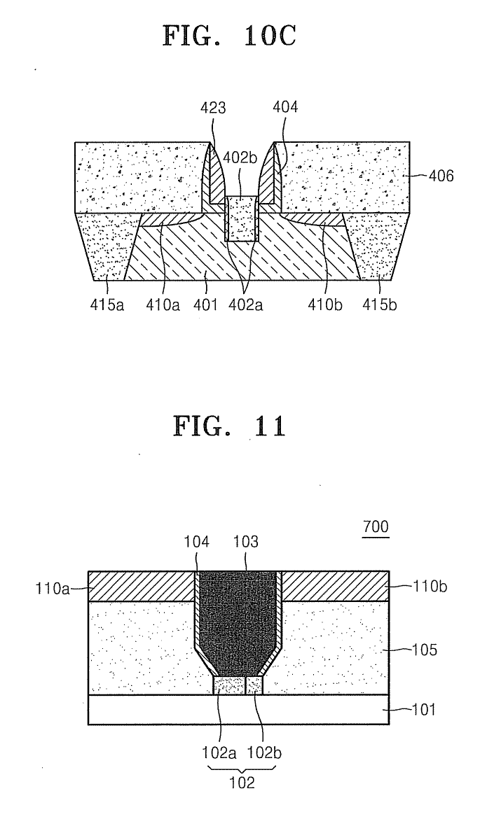

FIGS. 10A through 10C are schematic cross-sectional views illustrating a method of manufacturing the semiconductor device of FIG. 9.

First, the processes illustrated in FIGS. 7A through 7E are performed. Then, referring to FIG. 10A, a recess region 408 is partially formed in a channel layer 401.

Then, referring to FIG. 10B, the first variable resistance material layer 402a may be formed on inner walls of the recess region 408 formed in the gate insulating layer 404 and the channel layer 401. For example, a variable resistance material may be entirely filled in the recess region 408 by using a CVD method or a PVD method, and then the variable resistance material formed in a central portion of the recess region 408 may be removed through etching. Then, the variable resistance material may be formed only on the inner walls of the recess region 408 formed in the gate insulating layer 404 and the channel layer 401. As illustrated in FIG. 10B, ions may be injected into the variable resistance material through halo ion implantation, thereby forming the first variable resistance material layer 402a with oxygen vacancy defects therein.

Then, referring to FIG. 100, the second variable resistance material layer 402b is formed between the first variable resistance material layers 402a. That is, the second variable resistance material layer 402b is formed in the central portion of the recess region 408. The first variable resistance material layer 402a, the second variable resistance material layer 402b, and the first variable resistance material layer 402a may be sequentially formed in the stated order in a direction from the source 410a to the drain 410b. Then, the processes illustrated in FIGS. 7G through 7I are performed, thereby completing the semiconductor device 600 illustrated in FIG. 9.

In the semiconductor device 600 illustrated in FIG. 9, the first variable resistance material layers 402a are respectively formed at both sides of the second variable resistance material layer 402b, but example embodiments are not limited thereto. For example, the semiconductor device 600 may include one first variable resistance material layer 402a and one second variable resistance material layer 402b. In this case, in the process illustrated in FIG. 10B, the variable resistance material may remain only on one of the inner walls of the recess region 408 formed in channel layer 401 and the gate insulating layer 404 by etching the variable resistance material filled in the recess region 408.

The variable resistance material layer having the above-described multi-layered structure may also be applied to the semiconductor devices 100, 200, and 300 illustrated in FIGS. 1, 3, and 4.

FIG. 11 is a schematic cross-sectional view illustrating a semiconductor device according to a still further example embodiment.

Referring to FIG. 11, the semiconductor device 700 may include an insulating substrate 101, a channel layer 105 disposed on the insulating substrate 101, a gate 103 at least partially extending from an upper portion of the channel layer 105 to an inner portion of the channel layer 105, a gate insulating layer 104 disposed to surround the gate 103, a variable resistance material layer 102 disposed between the insulating substrate 101 and the gate 103 and having a first variable resistance material layer 102a and a second variable resistance material layer 102b, and a source 110a and a drain 110b respectively disposed at both sides of the gate 103 on the channel layer 105.

The first variable resistance material layer 102a and the second variable resistance material layer 102b are disposed in a direction in which current flows between both channel layers 105, as illustrated in FIG. 11. Thus, the first variable resistance material layer 102a and the second variable resistance material layer 102b may be disposed to directly contact both the insulating substrate 101 and the gate 103, and may be disposed adjacent to each other on the insulating substrate 101. Although FIG. 11 illustrates the variable resistance material layer 102 having a multi-layered structure is applied to the semiconductor device 100 of FIG. 1, the variable resistance material layer 102 may be similarly applied to the semiconductor devices 200 and 300 of FIGS. 3 and 4. Also, the variable resistance material layer 102 may have a triple-layered structure including the first variable resistance material layer 102a, the second variable resistance material layer 102b, and the first variable resistance material layer 102a in the stated order, similar to the embodiment described with reference to FIG. 9.

It should be understood that the example embodiments described herein should be considered in a descriptive sense only and not for purposes of limitation. Descriptions of features or aspects within each embodiment should typically be considered as available for other similar features or aspects in other embodiments.

What is claimed is:

1. A semiconductor device, comprising:
an insulating substrate;
a channel layer over the insulating substrate;
a gate at least partially extending from an upper surface of the channel layer to an inner portion of the channel layer;
a source and a drain respectively at opposing sides of the gate on the channel layer;
a gate insulating layer surrounding the gate and electrically insulating the gate from the channel layer, the source, and the drain; and
a variable resistance material layer between the insulating substrate and the gate.

2. The semiconductor device of claim 1, wherein the variable resistance material layer directly contacts the gate.

3. The semiconductor device of claim 1, wherein the gate insulating layer is between the variable resistance material layer and the gate.

4. The semiconductor device of claim 1, wherein the variable resistance material layer has a round bottom surface, a central portion of the round bottom surface of the variable resistance material layer that contacts the insulating substrate, and a peripheral portion of the round bottom surface that contacts the channel layer.

5. The semiconductor device of claim 1, wherein,
the channel layer is formed of a single crystalline semiconductor doped with a first conductive dopant, and
the source and the drain are formed of a single crystalline semiconductor doped with a second conductive dopant electrically opposite to the first conductive dopant.

6. The semiconductor device of claim 1, wherein the variable resistance material layer comprises a first variable resistance material layer with oxygen vacancy defects and a second variable resistance material layer with less oxygen vacancy defects than the first variable resistance material layer.

7. The semiconductor device of claim 6, wherein the first variable resistance material layer and the second variable resistance material layer are sequentially disposed in a path in which current flows.

8. The semiconductor device of claim 6, wherein the first variable resistance material layer and the second variable resistance material layer are adjacent to each other over the insulating substrate, and contact both the insulating substrate and the gate.

9. A semiconductor device, comprising:
a channel layer;
a source and a drain respectively on an upper portion of the channel layer;
a variable resistance material layer in a central upper portion of the channel layer between the source and the drain;
a gate over the variable resistance material layer; and
a gate insulating layer surrounding the gate.

10. The semiconductor device of claim 9, wherein the gate insulating layer surrounds at least a lower surface of the gate.

11. The semiconductor device of claim 10, wherein the gate insulating layer is between the lower surface of the gate and the channel, layer, and between the lower surface of the gate and the variable resistance material layer.

12. The semiconductor device of claim 10, wherein,
the variable resistance material layer directly contacts the gate, and
the gate insulating layer is between the lower surface of the gate and the channel layer.

13. The semiconductor device of claim 9, further comprising:
an insulating layer on both side surfaces of the channel layer to electrically insulate the semiconductor device from another semiconductor device of an adjacent cell.

14. The semiconductor device of claim 9, further comprising:
a passivation layer covering the source and the drain and surrounding one of the gate and the gate insulating layer.

15. The semiconductor device of claim 14, further comprising:
a source electrode and a drain electrode extending through the passivation layer, and electrically connected to the source and the drain, respectively.

16. The semiconductor device of claim 9, wherein the variable resistance material layer at least partially extends into the channel layer, and the variable resistance material layer protrudes from the channel layer.

17. The semiconductor device of claim 9, wherein,
the channel layer is doped with a first conductive dopant, and
the source and the drain are doped with a second conductive dopant which is electrically opposite to the first conductive dopant.

18. The semiconductor device of claim 17, further comprising:
a doped region in a portion of the channel layer surrounding a lower portion of the variable resistance material layer, the doped region being doped with the first conductive dopant at a higher doping concentration than a remaining portion of the channel layer.

19. The semiconductor device of claim 9, wherein the variable resistance material layer comprises a first variable, resistance material layer with oxygen vacancy defects and a second variable resistance material layer with less oxygen vacancy defects than the first variable resistance material layer.

20. The semiconductor device of claim 19, wherein the first variable resistance material layer and the second variable resistance material layer are sequentially disposed in a path in which current flows between the source and the drain.

21. The semiconductor device of claim 19, wherein,
the variable resistance material layer comprises the first variable resistance material layer, the second variable resistance material layer, and a third variable resistance material layer that are sequentially disposed in a path in which current flows between the source and the drain, and
the first and third variable resistance material layers are identical.

22. A method of manufacturing a semiconductor device, the method comprising:
preparing a structure including,
an insulating substrate,
a channel layer formed on the insulating substrate, and
a source and a drain respectively disposed on an upper portion of the channel layer;
forming a recess region in the channel layer by partially etching the channel layer between the source and the drain;
forming a first gate insulating layer on an entire inner wall of the recess region;
partially removing both the first gate insulating layer formed on a bottom surface of the recess region and the channel layer to expose a surface of the insulating substrate;
forming a variable resistance material layer on the surface of the insulating substrate in the recess region; and
forming a gate by depositing a gate electrode material in the recess region.

23. The method of claim 22, wherein the preparing a structure comprises:
preparing a transistor comprising,
the insulating substrate,
the channel layer formed on the insulating substrate,
the source and the drain respectively disposed on an upper surface of the channel layer,
a temporary gate partially formed between the source and the drain on the upper surface of the channel layer,
an insulating layer surrounding a lower surface of the temporary gate, and
a passivation layer formed on the upper surface of the channel layer and surrounding the insulating layer and the temporary gate;
polishing the passivation layer to expose the temporary gate; and
forming a through hole in the passivation layer by selectively etching the temporary gate and the insulating layer to expose the upper surface of the channel layer.

24. The method of claim 23, wherein,
the forming a through hole includes removing the insulating layer formed under the temporary gate, and
a portion of the insulating layer formed on a side surface of the temporary gate remains on a side wall of the through hole of the passivation layer.

25. The method of claim 23, wherein the forming a recess region comprises partially etching the channel layer exposed through the through hole.

26. The method of claim 23, further comprising:
forming contact holes in the passivation layer, and
forming a source electrode and a drain electrode respectively connected to the source and the drain by depositing an electrode material in the contact holes.

27. The method of claim 22, further comprising:
forming a second gate insulating layer on the variable resistance material layer, after the forming a variable resistance material layer on the surface of the insulating substrate in the recess region.

28. The method of claim 22, wherein the channel layer is etched such that the recess region has a round bottom surface.

29. The method of claim 22, wherein the forming a variable resistance material layer on the surface of the insulating substrate in the recess region comprises:
forming a first variable resistance material layer on an inner wall of the recess region;
removing the first variable resistance material layer formed in a central portion of the recess region;
forming oxygen vacancy defects in the first variable resistance material layer by using an ion injection method; and
forming a second variable resistance material layer in the central portion of the recess region.

30. A method of manufacturing a semiconductor device, the method comprising:
preparing a structure comprising,
a channel layer,
a source and a drain formed by doping an upper surface of the channel layer,
a temporary gate disposed between the source and the drain on the upper surface of the channel layer,
a gate insulating layer surrounding a lower surface and side surfaces of the temporary gate, and
a passivation layer formed on the channel layer to surround the gate insulating layer;
forming an opening by removing the temporary gate to expose a bottom surface of the gate insulating layer;
forming a recess region in the channel layer by partially etching both the bottom surface of the gate insulating layer in the opening and the channel layer below the gate insulating layer;
forming a variable resistance material layer in the recess region; and
forming a gate by depositing a gate electrode material in the opening on the variable resistance material layer.

31. The method of claim 30, wherein,
the channel layer is formed by doping a single crystalline semiconductor substrate with a first conductive dopant, and
the source and the drain are doped with a second conductive dopant which is electrically opposite to the first conductive dopant.

32. The method of claim 30, wherein, during the forming an opening by removing the temporary gate, the gate insulating layer remains on an inner wall of the opening.

33. The method of claim 32, wherein the forming a recess region comprises:
depositing a mask on the passivation layer and the gate insulating layer;
removing portions of the mask to form a mask pattern that surrounds the inner wall of the opening, exposes a central portion of the bottom surface of the opening and covers a peripheral portion of the bottom surface of the opening;
removing the bottom surface of the gate insulating layer that is not covered by the mask pattern; and
partially removing the channel layer.

34. The method of claim 33, after the forming a variable resistance material layer in the recess region, further comprising:
forming the bottom surface of the gate insulating layer between the mask pattern to cover an upper surface of the variable resistance material layer; and
removing the mask pattern formed on side walls of the gate insulating layer.

35. The method of claim 30, after the forming a recess region, further comprising:
forming a doped region in the channel layer around the recess region by injecting ions into the channel layer around the recess region.

36. The method of claim 30, wherein the forming a variable resistance material layer in the recess region comprises:
forming a first variable resistance material layer on an inner wall of the recess region and removing the first variable resistance material layer formed in a central portion of the recess region;
forming oxygen vacancy defects in the first variable resistance material layer by using an ion injection method; and
forming a second variable resistance material layer in a central portion of the recess region.

37. A semiconductor device, comprising:
a multi-layered channel including a first channel layer and a second channel layer, the second channel layer including a variable resistance material;
a source and a drain respectively on opposing ends of the multi-layered channel; and
a gate electrically insulated from the first channel layer, the source and the drain,
the second channel layer being interposed in an electrical path between the gate and the first channel layer.

38. The semiconductor device of claim 37, wherein one of the second channel layer and the gate is recessed within the first channel layer and protrudes from an upper surface of the first channel layer.

39. A method of manufacturing a semiconductor device, comprising:
providing a switching structure including,
a channel layer,
a source and a drain on the channel layer,
a temporary gate over the channel layer and insulated from the source, the drain and the channel layer by an insulating layer, and
a passivation layer covering an upper surface of the temporary gate;
forming an opening that exposes a portion of the channel layer by sequentially polishing the passivation layer from the upper surface of the temporary gate and etching to remove the temporary gate;
forming a recess region in the channel layer by removing the insulating layer from a bottom surface of the opening;
forming a variable resistance layer in a bottom portion of the recess region and contacting the channel layer; and
forming a gate over the variable resistance material layer by filling in a remaining portion of the recess region with a gate electrode material, the gate being insulated from the source, the drain and the channel layer.

40. The method of claim 39, prior to the forming a variable resistance layer, further comprising:
depositing a gate insulating layer in the recess region; and
removing the gate insulating layer on a bottom surface of the recess region and the channel layer under the bottom surface of the recess region to expose an insulating substrate.
